(19) United States
(12) Patent Application Publication
(10) Pub. No.: US 2026/0182460 A1
(43) Pub. Date: Jun. 25, 2026

(54) SEMICONDUCTOR DEVICE WITH PATTERNED WAVE GUIDE AND SELF-ALIGNED COMPONENT PLACEMENT

(71) Applicant: Microchip Technology Inc., Chandler, AZ (US)

(72) Inventors: Bomy Chen, Newark, CA (US); Steve Nagel, Chandler, AZ (US)

(73) Assignee: Microchip Technology Inc., Chandler, AZ (US)

(21) Appl. No.: 19/203,292

(22) Filed: May 9, 2025

Related U.S. Application Data
(60) Provisional application No. 63/736,714, filed on Dec. 20, 2024.
(60) Provisional application No. 63/736,683, filed on Dec. 20, 2024.

(51) Int. Cl. H01L 25/16; G02B 6/43; H01L 21/48; H01L 21/62; H01L 25/00

(52) U.S. Cl. CPC H10W 90/00; G02B 6/43; H10P 95/00; H10W 70/027

(57) ABSTRACT

Disclosed is a method of panel level packaging of one or more devices. The method comprises: providing a carrier, forming at least one optical waveguide on the carrier, selectively removing the at least one optical waveguide to obtain one or more opening areas, and mounting one or more components to the carrier within the one or more opening areas. Also disclosed is a panel level packaged device, comprising one or more of a photonic integrated circuit and an electronic integrated circuit; and a carrier, having a mounting side with at least one patterned optical waveguide. The photonic integrated circuit and/or the electronic integrated circuit are mounted into one or more opening areas of the at least one patterned optical waveguide.

### CROSS-REFERENCE TO RELATED APPLICATIONS

This application claims priority to U.S. provisional application U.S. 63/736,714, filed on Dec. 20, 2024, and U.S. provisional application U.S. 63/736,683 filed on Dec. 20, 2024. The contents of the aforesaid patent applications are incorporated herein for all purposes.

### FIELD OF THE INVENTION

The present disclosure relates to thermal management of integrated semiconductor devices, such as optical or electrical components.

### BACKGROUND

Modern electronic devices comprise a multitude of integrated components. Some applications require optical components, which may comprise lasers or other photonics components.

Recent developments increasingly add optical components in a in a co-packaged setup (co-packaged optics—CPO), for example to enable high speed data communications using optical transmitters or transceivers.

However, adding optical components increases the complexity and cost of a corresponding device. One reason being that in addition to electrical connections, optical connections generally need to be formed. These connections may require additional production steps, many of which require high precision, adding to the cost of the device.

### SUMMARY

There is a need for an improved manufacturing of an electronic device, such as for example in a CPO integrated setup. The need is addressed by the subject matter of the independent claim(s). Embodiments of the invention are described in the dependent claims, the following description, and the drawings.

### BRIEF DESCRIPTION OF THE DRAWINGS

FIG. 1 illustrates an example carrier with example integrated semiconductor devices in a perspective view.

FIG. 2 illustrates a cross-section through an example carrier that has a fin-array as a heat sink.

FIG. 3 illustrates the example carrier of FIG. 2 with added filler material.

FIG. 4A illustrates a cross-section through the example carrier of FIG. 2 with a waveguide.

FIG. 4B illustrates a cross-section through the example carrier of FIG. 2 with a stencil mask applied to the waveguide.

FIG. 4C illustrates a cross-section through the example carrier of FIG. 2 with self-aligning opening areas in the waveguide.

FIG. 4D illustrates a cross-section through the example carrier of FIG. 2 with the stencil mask removed.

FIG. 4E illustrates a cross-section through the example carrier of FIG. 2 with components inserted into the opening areas.

FIG. 5 illustrates the example carrier of FIGS. 4A-4E with added redistribution layers.

FIG. 6 illustrates the example integrated semiconductor device of FIG. 1, where the filler material has been removed.

FIG. 7 shows a top plan view of an example integrated semiconductor device.

FIG. 8 illustrates an example integrated semiconductor device in a cross-section after a portion of the metal carrier has been removed.

FIG. 9 illustrates the example integrated semiconductor device of FIG. 8 with additional packaging material.

FIG. 10 illustrates another example carrier with example integrated semiconductor devices in a perspective view.

### DESCRIPTION

The details of one or more embodiments are set forth in the accompanying drawings and the description below. Other features will be apparent from the description, drawings, and from the claims.

In the following description of embodiments of the invention, specific details are described in order to provide a thorough understanding of the invention. However, it will be apparent to one of ordinary skill in the art that the invention may be practiced without these specific details. In other instances, well-known features have not been described in detail to avoid unnecessarily complicating the instant description.

Some embodiments concern a method of panel level packaging of one or more devices, such as for example one or more optical devices or co-packaged optics (CPO) devices comprising electrical components and optical/optics components. In the context of the present discussion, the term ‘panel level packaging’ is understood according to the usual understanding in the art, namely a semiconductor packaging process using panels/carriers. Panel level packaging enables high-volume production with relatively low material waste.

The carrier may be of any suitable type and format. For example, the carrier may be made of metal or a metallic (composite) material, such as, e.g., aluminum or steel. The carrier may be made by any suitable process. For example, the carrier may be made by molding/casting, machining (such as milling), or 3D (metal powder) printing. The carrier may in some embodiments be rectangular with a size of 515 mm×510 mm or 600 mm×600 mm. Alternatively and in some embodiments, the carrier may be round with a diameter of 12 inch or 24 inch. It is noted that, in the context of the present disclosure, the terms ‘carrier’ and ‘panel’ are used interchangeably.

In some embodiments, at least one optical waveguide is formed on the carrier. In the context of the present discussion, the term ‘optical waveguide’ is understood according to its typical meaning in the art, namely a structure that channels or guides light along a given path.

The at least one optical waveguide may be formed with any suitable method. The one or more optical waveguides may be bonded to the carrier or manufactured in place on the carrier, e.g., using refractive coatings for cladding and core of the waveguide. In some embodiments, the one or more optical waveguides are arranged on a component side of the carrier.

In some embodiments, forming the at least one optical waveguide comprises applying at least two cladding layers and at least one core layer to the carrier. In such a setup, the at least one optical waveguide may be referred to as a strip waveguide. In some embodiments, the cladding and/or core layers are made from a glass or polymer material. For example, a nitride or polysilicon may be used for the core layer. For example, Si3N4, pSi, or c-Si may be used for the waveguide core layer. In some embodiments, a polymer, oxide, or glass may be used for the cladding. For example, SiO2 or a polymer with a lower refractive index n may be used. In some embodiments, a lithography process is used to manufacture the at least one optical waveguide.

Generally, the refractive index contrast of the at least one optical waveguide is selected according to the respective application. One consideration in this context may, e.g., be the wavelength of the light to be transmitted. In some embodiments, the core layer has a refractive index of n=1.55 and the cladding layers have a refractive index of n=1.45.

Some embodiments comprise selectively removing the at least one waveguide to obtain one or more opening areas. Any suitable operation for selectively removing the at least one waveguide may be used. In some embodiments, selectively removing the at least one waveguide comprises etching the waveguide. For example, a wet etch may be used. In some embodiments, in the opening areas, the at least one waveguide is removed to expose a surface of the carrier. This may be particularly useful to allow an improved transfer of heat from the one or more components to the carrier, the latter of which then effectively may be a heat sink. The one or more opening areas may be of any suitable shape. In some embodiments, the one or more opening areas may each have at least one dimension between 1-50 mm, for example of square shape.

Some embodiments comprise mounting one or more components to the carrier within the one or more opening areas. The components may be of any suitable type, such as electrical/electronic semiconductor components (e.g., an electronic integrated circuit—EIC), mechanical components, or optical/optics components (e.g., a photonic integrated circuit—PIC). In some embodiments, the one or more components may each have at least one dimension between 1-50 mm. In some embodiments, the one or more components are of square shape.

In some embodiments, the one or more components comprise one or more of a laser, a diode light source, and a photonic integrated circuit. In some embodiments, the one or more devices are co-packaged optics (CPO) devices, and the one or more components comprise at least one electrical/electronic component (electronic integrated circuit) and at least one optics/optical component (photonic integrated circuit). CPO arrangements allow for particularly small and efficient devices. In some embodiments, one or more components comprise a high-power component, such as a laser. In some embodiments, the method comprises forming a thermally conductive connection between the high-power component and the carrier such as by soldering or bonding.

The one or more components may be attached to the carrier with any suitable process. For example, the one or more components may be soldered to the carrier. In some embodiments, the one or more components are bonded to the carrier using, e.g., a thermally conductive material to allow an improved heat dissipation from the component to the carrier during use. In some embodiments, a Thermal Interface Material (TIM) adhesive or gel is used to bond the one or more components to the carrier.

In some embodiments, the one or more opening areas are configured to allow a self-aligning mounting of at least a first component of the one or more components to the carrier. A self-aligning mounting in the present context means that the first component aligns with a first opening of the one or more opening areas substantially by itself during mounting. In some embodiments, a self-aligning mounting is provided by establishing a form-fit or a half form-fit between the one or more opening areas and the one or more components to be mounted.

In some embodiments, (outer) dimensions of the one of more opening areas may substantially correspond to (outer) dimensions of the one or more components to allow a self-alignment of at least one of the one or more components to at least one of the one of more opening areas. For example, the outer dimensions of a part of a housing of the component may be configured to be essentially the same or slightly smaller than the inner dimensions of the respective opening area where the component is to be mounted, which provides a form-fit. In some embodiments, the form-fit provides a (linear and/or rotational) tolerance between 5-50 microns.

A self-aligning mounting is for example beneficial for PICs and may include aligning the optical outputs and/or optical inputs of the respective PIC with respective waveguides. However, a self-aligning mounting may also be beneficial for E ICs or mechanical components as it simplifies manufacturing of the one of more devices.

It is noted in this context that the ‘self-aligning mounting’ in some embodiments may still require some external alignment. In some embodiments, the self-aligning mounting provides a coarse alignment. A fine alignment may then be conducted in further active or passive alignment operations.

In some embodiments, selectively removing the at least one waveguide comprises applying a stencil mask. The stencil mask may for example be used in case selectively removing the at least one waveguide is conducted by etching. In some embodiments, the stencil mask is made of metal.

In some embodiments, the setup of EIC/PIC may increase from 2P2M to 8P-8M with an example pitch 50→0.5 um RDL′ line/space. In some embodiments, the stencil mask can fit two or more chiplets in single poly-rectangle.

In some embodiments, the method comprises providing the carrier with one or more cooling fins. The cooling fins may for example serve as a heat sink. Accordingly, instead of attaching a heat sink later to the finished product, the carrier is utilized as the heat sink in the present embodiments.

The present embodiments build on the (metal) heat sink carrier that has fins filled with polymer or oxide during packaging and may integrate optical waveguide circuitry with, e.g., self-aligned placement openings for lasers, EICs and/or PICs. Picking and placing the components directly into the waveguide built on a heat sink carrier allows to obtain some of the benefits of a CPO solution without having to build the optical components costly in silicon and simultaneously obtaining an improved heat transfer using the carrier fin design. This may allow for the direct coupling of the laser to the PIC at a controllable distance to balance cooling and size concerns.

The cooling fins may be of any suitable shape and size. In some embodiments, the fins have a length (perpendicular to the surface of the carrier) of 10-50 mm. In some embodiments, the cooling fins are formed integrally with the carrier, e.g., from the same material. In some embodiments, a plurality/multitude of cooling fins are provided. In some embodiments, the carrier is provided with the one or more cooling fins prior to forming the at least one optical waveguide on the carrier.

In some embodiments, the method comprises placing a filler material between at least two of the one or more cooling fins. The filler material may be of any suitable type to provide mechanical stability to the carrier and the cooling fins for the further assembly process. In some embodiments, the filler material is applied prior to forming the at least one optical waveguide on the carrier. For example, the filler material may comprise one or more of an oxide (e.g., SiO2) and a polymer. In some embodiments, the filler material is a placed between the one or more cooling fins so that at least a substantial portion of a space between the cooling fins is provided with filler material. In some embodiments, the filler material is placed in at least 80% of the space between the cooling fins. In some embodiments, the entire space, i.e., close to or exactly 100%, between the cooling fins is filled with filler material.

In some embodiments, the method comprises removing the filler material after mounting of the one or more components to the carrier. This can be done in any suitable way, for example using a mechanical, chemical, and/or thermal removal process. For example, a wet etch process may be used. Once the filler material is removed, the cooling fins may be exposed to a cooling medium during use of the device, such as a cooling gas or a cooling fluid.

In some embodiments, the carrier is sheetlike, and the one or more cooling fins are provided on a first surface of the carrier. In some embodiments, the one or more components are provided on a second surface of the carrier. The carrier thus may have a ‘heat sink side’ and a ‘component side’. In some embodiments, the thickness of the base of the carrier may be between 0.1-3 mm.

In some embodiments and prior to removing the filler material, a packaging material is arranged on at least parts of the carrier. The packaging material may be of any suitable type to partially or fully encase the one or more components. In some embodiments, a polymer is used as packaging material.

In some embodiments and prior to removing the filler material, a separating is conducted to obtain multiple separate devices. A separating—also referred to as dicing—refers to the separation of multiple devices that are formed on the same carrier. Separating prior to removing the filler material has the benefit of improved stability of the carrier during the separating process. Alternatively and in some embodiments, the separating is conducted after removing of the filler material. Doing so may increase efficiency as the filler material of multiple devices can be removed in a single operation.

In some embodiments, the method comprises forming at least one thermal break between a first component and a second component of the one or more components by at least partially removing the carrier between the first component and the second component. Forming the thermal break may be particularly beneficial to thermally isolate high-power components, such as lasers, diode light sources, transceivers, or power supplies, without limitation, from other components of the device.

In some embodiments, forming the at least one thermal break comprises partially removing the carrier between the first component and the second component at the intended location of the thermal break. Alternatively and in some embodiments, forming the at least one thermal break comprises completely removing the carrier at the intended location. In some embodiments, multiple thermal breaks are formed, where the carrier may be partially or fully removed.

Forming the at least one thermal break may be conducted in any suitable way. For example, a mechanical, chemical, or thermal at least partial removal of the carrier may be conducted. In some embodiments, at least partially removing the carrier comprises selectively applying a wet etch agent to a first surface of the carrier, on which first surface the one or more cooling fins are provided. In these embodiments, the carrier may be flipped upside-down, so that the one or more cooling fins face upwards for application of the wet etch agent. As will be easily apparent, the wet etch agent may be applied selectively, namely at the intended location(s) of the at least one thermal break. For example, a mask may be used to apply the wet etch agent at the intended location(s).

In some embodiments, selectively applying the wet etch agent comprises printing the wet etch agent. Using a printing process is particularly economic and allows a precise positioning of the at least one thermal break. In some embodiments, the wet etch agent is additionally used to at least partially remove the filler material, which may increase the efficiency of the process further.

Some embodiments relate to a panel level packaged device using the method described herein or one or more of the discussed embodiments.

Some embodiments relate to a panel level packaged device, comprising one or more of a photonic integrated circuit and an electronic integrated circuit, and a carrier. The carrier may have a mounting side with a patterned waveguide (layer), wherein the photonic integrated circuit and/or the electronic integrated circuit are mounted into one or more opening areas of the waveguide. In some embodiments, cooling protrusions are provided on a heat sink side of the carrier, opposite to the mounting side.

In some embodiments, the device comprises one or more of the photonic integrated circuits and one or more of the electronic integrated circuits in a co-packaged optics (CPO) arrangement.

In some embodiments, the device comprises one or more of lasers and diode light sources.

Some embodiments provide a (packaged) integrated semiconductor device with panel level packaging for one or more lasers, PICs (photonic integrated circuits) and EICs (electronic ICs) on a novel metal carrier, having a patterned waveguide. The waveguide comprises one or more opening areas into which the one or more lasers, PICs and EICs are mounted.

In some embodiments, the carrier serves as a heat sink. The carrier may have cooling fins with a fill material (e.g., an oxide or a polymer) between them at least during the packaging process for structural stability. The fill material protects the heat sink fins during panel level processing and provides improved rigidity. The fill material may be removed, e.g., at the end of the packaging operation, to expose the cooling fins to the respective medium of the environment (e.g., gas, fluid) during use.

A heat sink thus is integrated into the packaging process as a carrier and may be directly or indirectly attached to heat generating elements (e.g., a laser) to provide efficient cooling where needed. The heat sink or parts thereof can optionally be removed in areas where it is not needed or wanted, i.e., providing a thermal break. For example, a thermal break may be provided in an area where the heat sink could provide a path for unwanted heat conduction between elements.

In some embodiments, a packaged IC device may be provided, where elements are in close vicinity to each other. A heat sink is provided where needed as part of the processing or packaging.

In some embodiments, a new panel design for panel level packaging is comprised of a patterned heat sink that is backfilled with for example oxide or polymer for stability during processing. When processing is complete, the backfill material may be wet etched away, leaving a heat sink. Accordingly and in some embodiments, a dual use panel/carrier is provided that can be used for panel level packaging and that also acts as a heat sink for components that need to be cooled. In some embodiments, portions of the heat sink may be removed between components to provide a thermal break.

In some embodiments, the setup is lowering cost by using the carrier as a heat sink and also connecting the heat sink to the die(s) compared with using a glass carrier that can be a barrier to heat transfer and where a separate device for heat dissipation would be arranged.

In some embodiments, the device is an integrated device with co-packaged optics, i.e., a CPO IC. In some embodiments, the device comprises at least a high-power device that generates a lot of heat, for example an APID or DPG. In some embodiments, the device is a high-speed communications device. In some embodiments, the device may be used for an FPGA, DCS, or CBU or wherever ultra high-speed communications are needed.

In some embodiments, a carrier for panel level packaging of one or more devices is provided. The carrier may for example be sheetlike and comprises a first surface and a second surface, wherein the second surface comprises a patterned waveguide layer, comprising one or more opening areas configured to allow a self-aligning mounting of one or more components to the carrier. In some embodiments, one or more cooling fins are provided on the first surface.

In some embodiments, a method is provided, where a metal carrier is attached to one or more integrated components in a package using panel level packaging. The metal carrier has a built-in heat sink. The heat sink comprises a filler that is removed after processing. In an optional processing operation, a thermal break (etch) is provided between components for thermal insulation. This may allow for a closer placement and/or a smaller footprint.

Reference will now be made to the drawings in which the various elements of embodiments will be given numerical designations and in which further embodiments will be discussed.

In the embodiments described herein, the described components of the embodiments each represent individual features that are to be considered independent of one another, in the combination as shown or described, and in combinations other than shown or described. In addition, the described embodiments can also be supplemented by features other than those described.

Specific references to components, process steps, operations, and other elements are not intended to be limiting. Further, it is understood that like parts bear the same or similar reference numerals when referring to alternate FIGS. The FIGS. are schematic and not necessarily to scale.

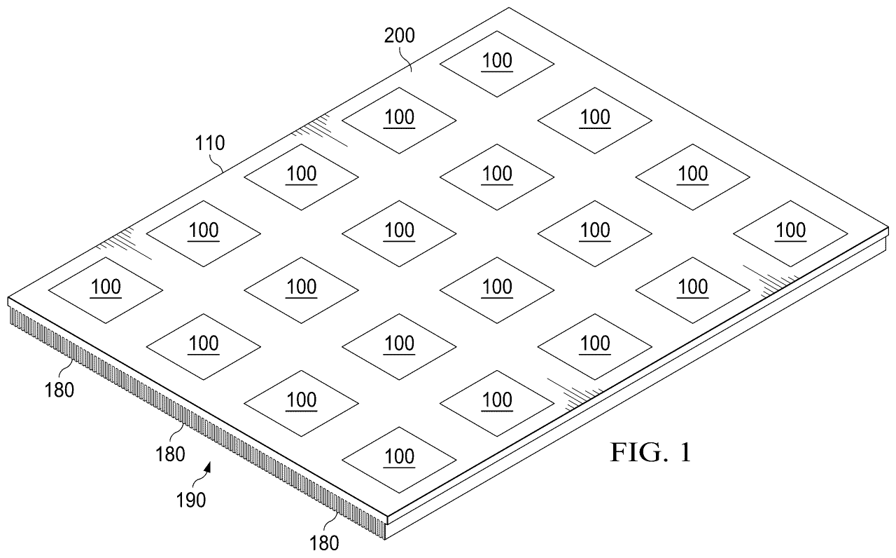

Embodiments relate to a method of panel level packaging (PLP) and a device, manufactured by PLP. The method begins by providing a carrier/panel 110, as shown in a perspective view in FIG. 1. The carrier 110 is rectangular with a size of 600 mm×600 mm and is made of metal (e.g., Al or SS). The thickness of the base of the carrier 110 is between 0.1-3 mm.

To manufacture the carrier 110, any suitable method of metal forming may be used, such as casting, milling, or 3D (metal powder) printing.

The carrier 110 may optionally be provided with a fin-array with a multitude of fins 180 on a first surface 190. Alternatively, a carrier 110a without fins may be used, as shown in the perspective view of FIG. 10.

The fins 180 of the embodiments of FIG. 1 serve as a heat sink for components 130, 140, 150 (not shown in FIG. 1) that are mounted to a second surface 200, also referred to herein as a mounting side. The fins 180 have a height of between 10-50 mm. As will be apparent to one skilled in the field of panel level packaging, the carrier 110 is used to manufacture a number of integrated semiconductor devices 100. The later positioning of these devices 100 on the carrier 110 is indicated in the schematic view of FIG. 1 by rectangular fields. Each corresponding field corresponds to a single device 100.

In the following, an example of a method of panel level packaging (PLP) will be discussed with reference to the manufacture of a single device 100. It will be appreciated however, that the method may be applied simultaneously to all devices 100 on the carrier 110. Corresponding to typical semiconductor manufacturing, a separation/dicing operation is conducted at the end of the process to provide multiple separate devices 100.

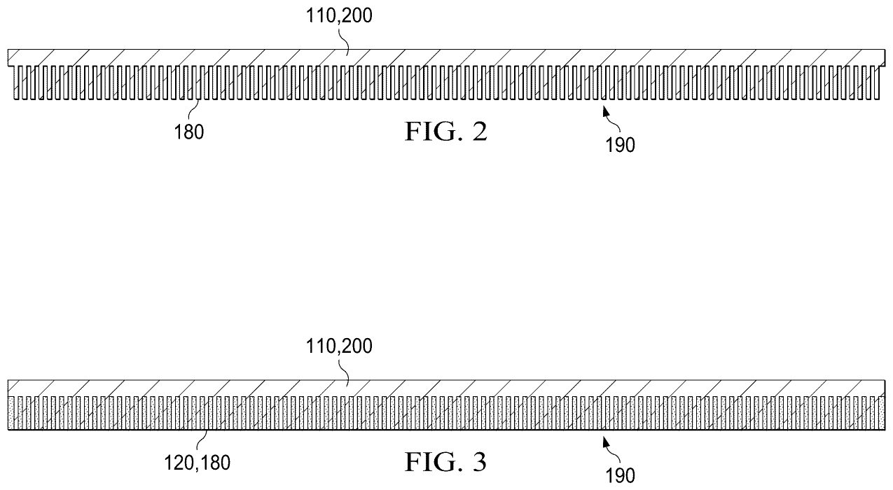

FIG. 2 shows a cross-sectional view of the example carrier 110 with cooling fins 180. According to the present embodiments, the method provides placing a filler material 120 into the spaces between the individual cooling fins 180. This is shown in the cross-sectional view of FIG. 3. The filler material 120 may for example be SiO2 or a polymer and is used to provide stability during the panel level packaging process as well as to protect the cooling fins 180 from mechanical damage using the processing.

In the case of SiO2 (glass) as filler material 120, a spin-on process may be used. In the case of a polymer as filler material 120, a liquid application, followed by a curing process (e.g., heat and/or UV light), may be used. In some embodiments, multiple curing operations are conducted (e.g., 2-3 rounds of curing) to obtain a polymeric filler 120 of sufficient density/stability.

As discussed in the preceding, a purpose of filler material 120 is to provide sufficient mechanical stability for the packaging operations and to avoid damage to the fins 180 of the carrier 110.

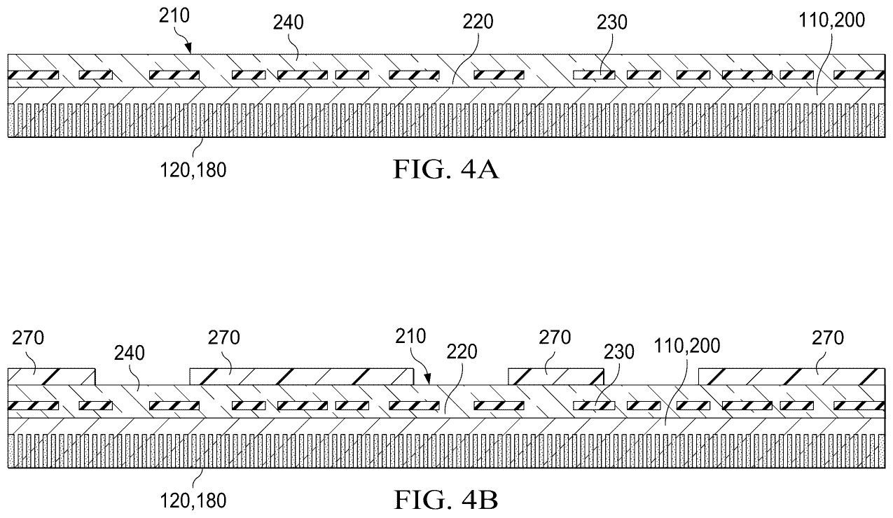

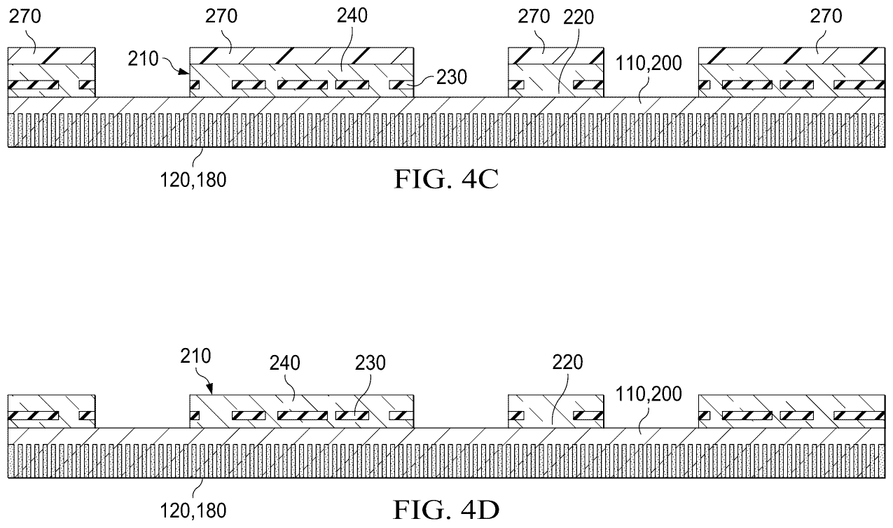

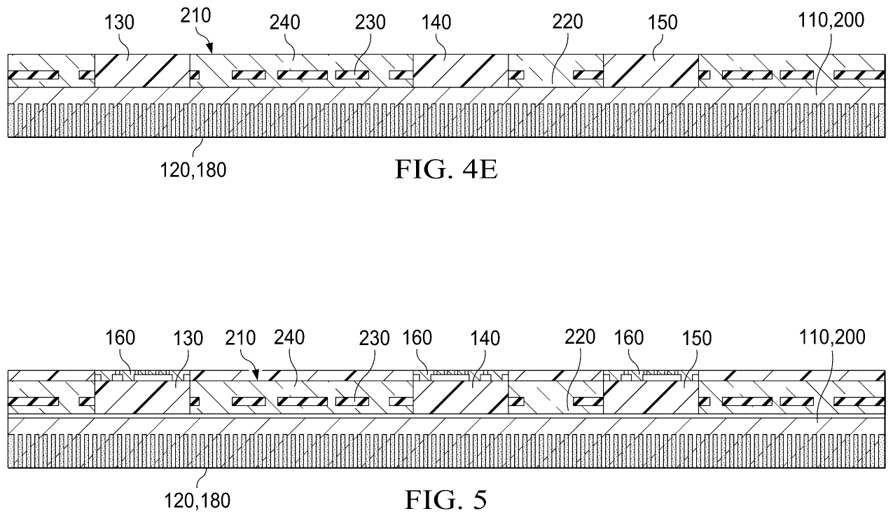

Once the filler material 120 is in place between the fins 180, a waveguide 210 is formed on the carrier 110 or more precisely on second surface 200 of carrier 110, as shown in FIG. 4A.

The waveguide 210 comprises a lower cladding 220, a waveguide core 230, and an upper over cladding 240. The waveguide 210 may be manufactured using any suitable process and may be of any suitable materials. For example, a nitride or polysilicon may be used as the waveguide core 230. For example, Si3N4, pSi, or c-Si may be used for the waveguide core 230. For example, a polymer, oxide, or glass may be used for the cladding 220, 240. For example, SiO2 or a polymer with a lower refractive index n may be used (e.g., n=1.45 for the cladding and n=1.55 for the core).

It is noted that the waveguide core 230 is shown in the cross-section of FIG. 4A as a discontinuous layer. This is due to the fact that the waveguide core 230 is patterned based on the routing of optical connections within device 100, similar to the routing of electrical connections on a printed circuit board. In some embodiments, a lithography process is used to manufacture the patterned waveguide core 230.

As shown in FIG. 4B, a metal stencil mask 270 is applied to the top of waveguide 210. The stencil mask 270 allows to etch the waveguide 210. For example, a wet etch may be used. As shown in FIG. 4C, the waveguide 210 is etched in several opening areas, corresponding to where the stencil mask has openings. In these opening areas, the waveguide 210 is completely removed, exposing the top surface 200 of carrier 110. The opening areas are matched closely to the outer dimensions of one or more components (within a tolerance of 5-50 microns in each dimension and/or rotationally), namely in this example, a laser 130, a PIC 140 (photonic integrated circuits), and an EIC 150 (electronic ICs), all not shown in FIG. 4C, to allow a self-aligning mounting of these components on the carrier 110.

The stencil mask 270 is subsequently removed, as shown in FIG. 4D. Laser 130, PIC 140 and EIC 150 are picked and placed in the opening areas in waveguide 210 and subsequently bonded to carrier 110, as shown in FIG. 4E. Since the opening areas in the waveguide 210 correspond to the outer dimensions of laser 130, PIC 140 and EIC 150, a fast and efficient self-aligning mounting of laser 130, PIC 140 and EIC 150 on the carrier 110 is enabled.

It should be readily understood that the teachings herein are not limited to three components 130, 140, 150. Instead, any number of components may be attached to the carrier 110, depending on the respective application.

The components are in this example mounted/bonded to carrier 110 using a thermal interface material (TIM), which helps to dissipate heat, generated by the components 130, 140, and 150 to the carrier 110 and to the environment.

Once the components 130, 140, 150 are mounted to surface 200 of the carrier 110, electrical connections may be formed through application of an optional redistribution layer 160 (copper embedded in polymer) and various optional contacts (not shown) on each component 130, 140, 150. In addition, the laser 130 and PIC 140 may be connected using the waveguide 210.

FIG. 5 shows the carrier 110 after the bonding of the components 130, 140, 150 and with redistribution layer 160 and waveguide 210. One or more optional packaging operations, such as for example separation/dicing, may then be conducted.

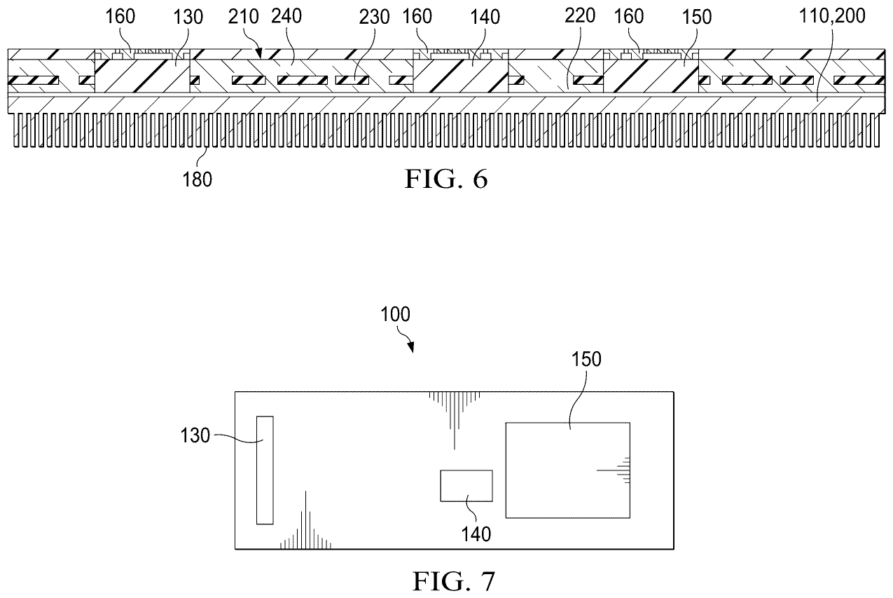

Once this is complete, the filler material 120 is removed to expose the fins 180 of the fin-array, as shown in FIG. 6. Removal of the filler material 120 may be conducted using any suitable process, depending on the respective filler material 120 used.

For an example SiO2 or polymeric filler material 120, a wet (etch) removal process may be used. Alternatively in case of a polymeric filler material 120, a thermal removal process may be used.

After the filler material 120 is removed and a separation/dicing is conducted, either before or after removal of the filler material 120, an integrated semiconductor device 100 is obtained, as shown in the plan view of FIG. 7.

In the present embodiments, the integrated semiconductor device 100 is of co-packaged setup (CPO), as it comprises electronic and photonic components, namely the laser 130, PIC 140 and EIC 150.

The integrated semiconductor device 100 may be further packaged, the package including but not limited to DIP (Dual-Inline Package), SOP (Small Outline Package), QFP (Quad Flat Package), TSOP (Thin Small Outline Package), PLCC (Plastic Leaded Chip Carrier), BGA (Ball Grid Array), W L P (Wafer Level Package), or another package type.

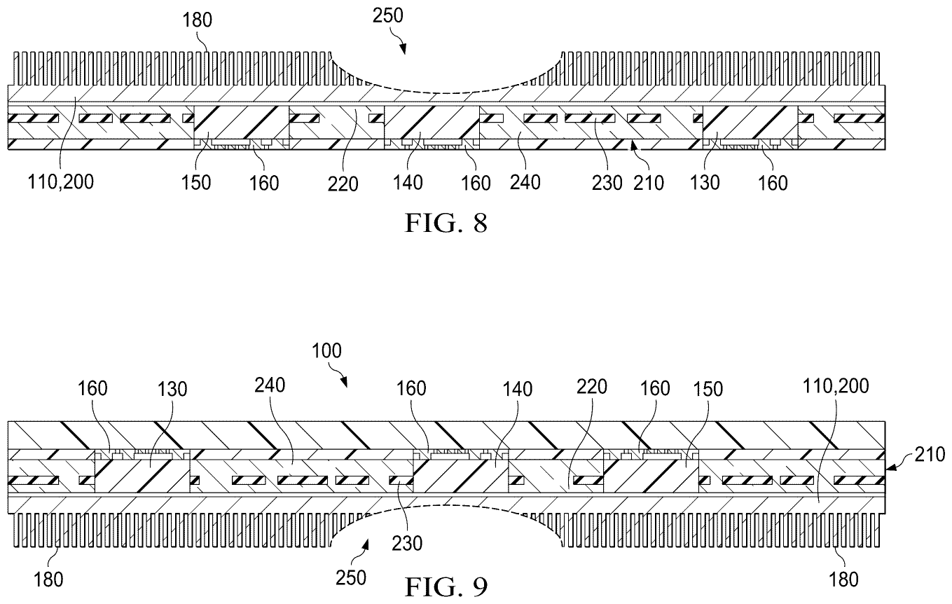

FIG. 8 shows an optional processing operation to obtain integrated semiconductor device 100, namely the introduction of one or more optional thermal breaks 250 into the carrier 110. This operation can be conducted either before or after removal of the filler material 120.

FIG. 8 illustrates the example carrier 110 in an upside-down cross-sectional view after a portion of the metal carrier 110 has been removed. The removal of the carrier 110 serves to reduce or prevent heat transfer from laser 130 to ICs 140, 150. As the inventors of the instant invention have determined, excessive heat from laser 130 may cause a degradation of performance in ICs 130, 140, depending on the physical distance between them.

To provide the thermal break 250, i.e., to partially remove the carrier 110, any suitable method may be used. For example, a flip panel 3D printed wet etch may be employed. Herein, an acid that can etch the material of carrier 110 is 3D printed in the desired area. For an example Al carrier, any fluid containing acid may be used that can etch aluminum, for example phosphoric acid.

In case the thermal breaks are introduced prior to removal of the filler material 120, a suitable wet etch agent may be used that can remove both, the filler 120 and the carrier 110 where desired. Although one thermal break is shown in the FIGS., it is noted that any number of thermal breaks may be provided, depending on the respective layout or requirements of the respective device.

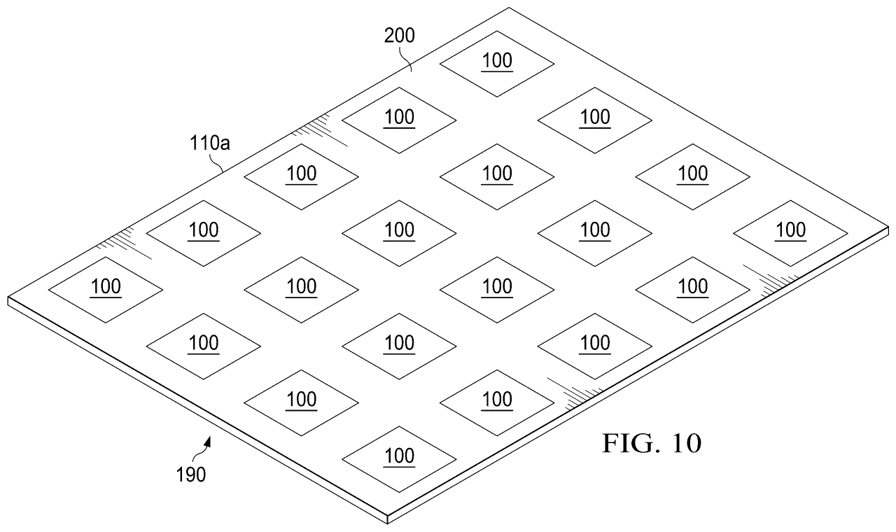

FIG. 9 shows the completed example integrated semiconductor device 100 in a cross-sectional view with the discussed thermal break 250 and with an optional packaging material 260 on top.

The invention has been described in the preceding using various example embodiments. Other variations to the disclosed embodiments may be understood and effected by those skilled in the art in practicing the claimed invention, from a study of the drawings, the disclosure, and the appended claims. In the claims, the word “comprising” does not exclude other elements or steps, and the indefinite article “a” or “an” does not exclude a plurality. A single processor, device, or other unit may be arranged to fulfil the functions of several items recited in the claims. Likewise, multiple processors, devices, or other units may be arranged to fulfil the functions of several items recited in the claims.

The mere fact that certain measures are recited in mutually different dependent claims or embodiments does not indicate that a combination of these measures cannot be used to advantage. Any reference signs in the claims should not be construed as limiting the scope.

What is claimed is:

1. A method of panel level packaging of one or more devices, comprising:
providing a carrier;
forming at least one optical waveguide on the carrier;
selectively removing the at least one optical waveguide to obtain one or more opening areas; and
mounting one or more components to the carrier within the one or more opening areas.

2. The method of claim 1, wherein the one or more opening areas are configured to allow a self-aligning mounting of the one or more components to the carrier.

3. The method of claim 1, wherein in the opening areas, the at least one optical waveguide is removed to expose a surface of the carrier.

4. The method of claim 1, wherein the carrier is made of metal.

5. The method of claim 1, wherein forming the at least one optical waveguide comprises applying at least two cladding layers and at least one core layer to the carrier.

6. The method of claim 1, wherein selectively removing the at least one optical waveguide comprises etching the at least one optical waveguide.

7. The method of claim 1, wherein selectively removing the at least one optical waveguide comprises applying a stencil mask.

8. The method of claim 1, wherein dimensions of the one or more opening areas substantially correspond to outer dimensions of the one or more components to allow a self-alignment of at least one of the one or more components to at least one of the one or more opening areas.

9. The method of claim 1, comprising:
providing the carrier with one or more cooling fins;
placing a filler material between at least two of the one or more cooling fins; and
removing the filler material after mounting of the one or more components to the carrier.

10. The method of claim 9, wherein the carrier is sheetlike, the one or more cooling fins are provided on a first surface of the carrier, and the one or more components are mounted to a second surface of the carrier.

11. The method of claim 1, wherein the one or more devices are co-packaged optics devices, and the one or more components comprise at least one electronic component and at least one optical component.

12. The method of claim 1, wherein the one or more components comprise one or more of a laser, a diode light source, and a photonic integrated circuit.

13. The method of claim 1, comprising forming at least one thermal break between a first component and a second component of the one or more components by at least partially removing the carrier between the first component and the second component.

14. The method of claim 13, wherein at least partially removing the carrier comprises selectively applying a wet etch agent to a first surface of the carrier, on which first surface one or more cooling fins are provided.

15. The method of claim 14, wherein selectively applying the wet etch agent comprises printing the wet etch agent.

16. The method of claim 1, wherein the one or more components comprise a high-power component, the method comprising forming a thermally conductive connection between the high-power component and the carrier.

17. A panel level packaged device, manufactured with the method of claim 1.

18. A panel level packaged device, comprising:
one or more of a photonic integrated circuit and an electronic integrated circuit; and
a carrier, having a mounting side with at least one patterned optical waveguide; wherein
the photonic integrated circuit and/or the electronic integrated circuit are mounted into one or more opening areas of the at least one patterned optical waveguide.

19. The panel level packaged device of claim 18, comprising at least the photonic integrated circuit and the electronic integrated circuit in a co-packaged optics arrangement.

20. A carrier for panel level packaging of one or more devices, wherein the carrier is sheetlike and comprises a first surface and a second surface, wherein the second surface comprises at least one patterned optical waveguide layer, comprising one or more opening areas configured to allow a self-aligning mounting of one or more components to the carrier.
